(19) United States
(12) Patent Application Publication
(10) Pub. No.: US 2023/0260942 A1
(43) Pub. Date: Aug. 17, 2023

(54) BOND ROUTING STRUCTURE FOR STACKED WAFERS

(71) Applicant: Taiwan Semiconductor Manufacturing Company, Ltd., Hsinchu (TW)

(72) Inventors: Harry-Hak-Lay Chuang, Zhubei City (TW); Li-Feng Teng, Hsinchu City (TW); Wei Cheng Wu, Zhubei City (TW)

(21) Appl. No.: 17/750,746

(22) Filed: May 23, 2022

Related U.S. Application Data
(60) Provisional application No. 63/310,781, filed on Feb. 16, 2022.

(51) Int. Cl. H01L 23/00; H01L 25/065

(52) U.S. Cl. CPC H01L 24/08; H01L 24/80; H01L 25/0657; H01L 2224/80896; H01L 2224/80895; H01L 2924/1431; H01L 2924/1421; H01L 2924/3511; H01L 2224/08147; H01L 2224/0231; H01L 2224/02331; H01L 2224/02372; H01L 2224/02371; H01L 2224/02381; H01L 2224/02375; H01L 2224/02373; H01L 2224/0801; H01L 2224/08146; H01L 2225/06524; H01L 2225/06527; H01L 2225/06544; H01L 2224/08121

(57) ABSTRACT

Various embodiments of the present disclosure are directed towards an integrated circuit (IC) having a first IC structure that includes a first substrate, a first interconnect structure, and a first hybrid bond structure. The second IC structure includes a second substrate and a second hybrid bond structure abutting the first hybrid bond structure at a bond interface. The second substrate includes first and second device regions including first semiconductor devices and second semiconductor devices. The first semiconductor devices being of a first type of IC device and the second semiconductor devices being of a second type of IC device different than the first type of IC device. A bond routing structure couples the first interconnect structure to the first and second semiconductor devices. A lateral routing structure continuously laterally extends from under the first device region to under the second device region.

### REFERENCE TO RELATED APPLICATION

This application claims the benefit of U.S. Provisional Application No. 63/310,781, filed on Feb. 16, 2022, the contents of which are incorporated by reference in their entirety.

### BACKGROUND

The semiconductor industry has continually improved the processing capabilities and power consumption of integrated circuits (ICs) by shrinking the minimum feature size. However, in recent years, process limitations have made it difficult to continue shrinking the minimum feature size. The stacking of two-dimensional (2D) ICs into three-dimensional (3D) ICs has emerged as a potential approach to continue improving processing capabilities and power consumption of ICs. Conductive bond structures are used to electrically couple stacked 2D ICs together.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a multi-dimensional integrated circuit (IC) structure comprising a first IC structure bonded to a second IC structure, where the second IC structure comprises conductive bond layers configured to route electrical connections between the first and second IC structures.

FIG. 2 illustrates a perspective view of some embodiments of a region of the multi-dimensional IC structure of FIG. 1.

FIG. 3 illustrates a cross-sectional view of some different embodiments of the multi-dimensional IC structure of FIG. 1, where the second IC structure comprises multiple layers of a plurality of lateral routing structures.

FIG. 4 illustrates a perspective view of some embodiments of a region of the multi-dimensional IC structure of FIG. 3.

FIG. 5 illustrates a top view of some embodiments of the multi-dimensional IC structure of FIG. 3.

FIG. 6 illustrates a cross-sectional view of some different embodiments of the multi-dimensional IC structure of FIG. 3.

FIGS. 7 and 8 illustrate various perspective views of some embodiments of a region of the multi-dimensional IC structure of FIG. 6.

FIG. 9 illustrates a cross-sectional view of some different embodiments of the multi-dimensional IC structure of FIG. 3.

FIG. 10 illustrates a perspective view of some embodiments of a region of the multi-dimensional IC structure of FIG. 9.

FIG. 11 illustrates a cross-sectional view of some different embodiments of the multi-dimensional IC structure of FIG. 3.

FIG. 12 illustrates a perspective view of some embodiments of a region of the multi-dimensional IC structure of FIG. 11.

FIGS. 13 and 14 illustrate various cross-sectional views of some different embodiments of the multi-dimensional IC structure of FIG. 1.

FIG. 15 illustrates a perspective view of some embodiments of a first IC structure overlying a second IC structure.

FIGS. 16-23 illustrate a series of cross-sectional views of some embodiments of a method for forming a multi-dimensional IC structure comprising a first IC structure bonded to a second IC structure, where the second IC structure comprises conductive bond layers configured to route electrical connections between the first and second IC structures.

FIG. 24 illustrates a flowchart of some embodiments of a method for forming a multi-dimensional IC structure comprising a first IC structure bonded to a second IC structure, where the second IC structure comprises conductive bond layers configured to route electrical connections between the first and second IC structures.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A three-dimensional (3D) integrated circuit (IC) may comprise a first IC structure and a second IC structure stacked on the first IC structure. The first and second IC structures may respectively comprise a semiconductor substrate, an interconnect structure, and a bonding structure. The interconnect structures are between the semiconductor substrates, and the bonding structures between the interconnect structures. A first plurality of semiconductor devices (e.g., logic devices) is disposed on/within the semiconductor substrate of the first IC structure and a second plurality of semiconductor devices (e.g., input/output (I/O) devices, high-voltage (HV) devices, radio frequency (RF) devices, etc.) is disposed on/within the semiconductor substrate of the second IC structure. The interconnect structures comprise alternating stacks of wiring layers (e.g., horizontal routing) and via layers (e.g., vertical routing) and are configured to route electrical connections between respective semiconductor devices in the first and second IC structures. The bonding structures comprise bonding dielectric layers and conductive bonding layers. The bonding structure of the first IC structure meets the bonding structure of the second IC structure at a bonding interface.

The first plurality of semiconductor devices is electrically coupled to the second plurality of semiconductor devices by way of the conductive bonding layers and interconnect structures. The conductive bonding layers of the bonding structures are configured to facilitate good electrical connections and good bonding adhesion between the interconnect structures of the first and second IC structures. However, typically no electrical routing is performed in the conductive bonding layers, thereby limiting design flexibility of the first and second IC structures. For example, to facilitate proper electrical connection between semiconductor devices in the first and second IC structures, logic devices in the first IC structure configured to control semiconductor devices (e.g., I/O devices, HV devices, or RF devices) are laterally aligned with one another. Having corresponding semiconductor devices in the first and second IC structures laterally aligned with one another mitigates design flexibility of the first and/or second IC structures. In an attempt to increase design flexibility additional wiring layers and via layers may be added to the interconnect structures of the first and second IC structures. This may facilitate increase design flexibility, but increases resistance in the first and second IC structures, increases warpage of the semiconductor substrates, and increases costs/time to manufacture the 3D IC. Further, the first plurality of semiconductor devices may be electrically coupled to the second plurality of semiconductor devices by an interposer and/or the bonding structures may comprise one or more solder bumps. However, including the interposer and/or the one or more sold bumps increases a number of conductive structures used to couple the first and second plurality of semiconductor devices, thereby increasing resistance in the 3D IC and increasing costs/time to manufacture the 3D IC.

Various embodiments of the present application are directed towards a multi-dimensional IC structure comprising bond structures that respectively include conductive bonding layers configured to route electrical connections. The multi-dimensional IC structure comprises a first IC structure and a second IC structure vertically stacked with one another. The first and second IC structures respectively comprise a semiconductor substrate, an interconnect structure, and a hybrid bond structure. Further, the first IC structure has a first plurality of semiconductor devices predominately comprising a single type of IC device (e.g., a logic device) and the second IC structure has a second plurality of semiconductor devices disposed across various device regions each predominately comprising different types of IC devices (e.g., a first device region predominately comprising a first type of IC device and a second device region predominately comprising a second type of IC device different from the first type of IC device).

The hybrid bond structures comprise bond dielectric structures and conductive bond structures. The hybrid bond structures meet at a bond interface. Further, the hybrid bond structure of the second IC structure comprises a plurality of lateral routing structures (e.g., horizontal routing) and a plurality of vertical routing structures (e.g., vertical routing) configured to route electrical connections between semiconductor devices of the first and second IC structures. This mitigates the importance of aligning (e.g., laterally aligning) the first plurality of semiconductor devices with corresponding semiconductor devices in the second plurality of semiconductor devices, thereby increasing design flexibility. In addition, incorporating the electrical routing in the hybrid bond structures of the first and second IC structures mitigates the use of additional routing structures (e.g., such as an interposer, sold bumps, interconnect wires, interconnect vias, etc.) in the first and second IC structures, thereby decreasing a resistance, cost of manufacturing, and/or warpage of the multi-dimensional IC structure.

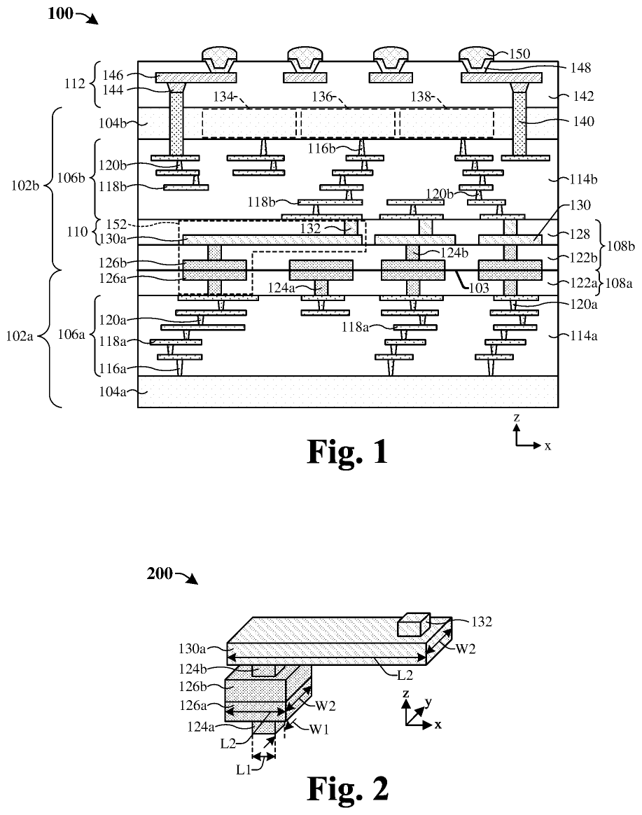

FIG. 1 illustrates a cross-sectional view 100 of some embodiments of a multi-dimensional integrated circuit (IC) structure comprising a first IC structure bonded to a second IC structure, where the second IC structure comprises conductive bond layers configured to route electrical connections between the first and second IC structures.

The multi-dimensional IC structure of FIG. 1 comprises a first IC structure 102a and a second IC structure 102b. The first and second IC structures 102a, 102b respectively comprise first and second substrates 104a, 104b, first and second interconnect structures 106a, 106b, and first and second hybrid bond structures 108a, 108b. The first and second substrates 104a, 104b may, for example, be or comprise a silicon-on-insulator substrate (SOI), bulk silicon, monocrystalline silicon, silicon germanium, epitaxial silicon, some other type of semiconductor substrate, or a combination of the foregoing. In various embodiments, the first and second substrates 104a, 104b may each be referred to as a semiconductor wafer or a semiconductor substrate.

Further, a first plurality of semiconductor devices (not shown) may be disposed within and/or on the first substrate 104a. The first plurality of semiconductor devices of the first IC structure 102a may be logic devices or another suitable device. A second plurality of semiconductor devices (not shown) may be disposed within and/or on the second substrate 104b. The second plurality of semiconductor devices are disposed across a plurality of device regions 134-138 of the second substrate 104b. For example, first semiconductor devices (not shown) may be disposed within and/or on a first device region 134 of the second substrate 104b, second semiconductor devices (not shown) may be disposed within and/or on a second device region 136 of the second substrate 104b, and third semiconductor devices (not shown) may be disposed within and/or on a third device region 138 of the second substrate 104b. The first, second, and third semiconductor devices may each be different from one another and/or may each be configured for different applications. In some embodiments, the first semiconductor devices in the first device region 134 may be radio frequency (RF) devices, the second semiconductor devices in the second device region 136 may be input/output (I/O) devices, and the third semiconductor devices in the third device region 138 may be high voltage (HV) devices. In various embodiments, the first and second substrates 104a, 104b each comprise a single continuous material (e.g., a single continuous layer of silicon or another suitable material). In some embodiments, the second substrate 104b comprises a single semiconductor material (e.g., such as silicon) that continuously laterally extends from and/or around the first, second, and third semiconductor devices in the plurality of device regions 134-138.

The first and second interconnect structures 106a, 106b are disposed between the first and second substrates 104a, 104b and are spaced apart from one another by the first and second hybrid bond structures 108a, 108b. The first interconnect structure 106a comprises a first interconnect dielectric structure 114a, a first plurality of conductive contacts 116a, a first plurality of conductive wires 118a, and a first plurality of conductive vias 120a. Similarly, the second interconnect structure 106b comprises a second interconnect dielectric structure 114b, a second plurality of conductive contacts 116b, a second plurality of conductive wires 118b, and a second plurality of conductive vias 120b. In some embodiments, the first and second interconnect dielectric structures 114a, 114b may respectively comprise a plurality of dielectric layers. The dielectric layers of the first and second interconnect dielectric structures 114a, 114b may, for example, be or comprise silicon dioxide, a low-k dielectric material, an extreme low-k dielectric material, some other dielectric material, or any combination of the foregoing. As used herein, a low-k dielectric material is a dielectric with a dielectric constant less than about 3.9. The first conductive wires 118a are alternatingly stacked with the first conductive vias 120a in the first interconnect dielectric structure 114a. The second conductive wires 118b are alternatingly stacked with the second conductive vias 120b in the second interconnect dielectric structure 114b.

An upper bonding structure 112 overlies the second substrate 104b. In some embodiments, the upper bonding structure 112 comprises a plurality of upper conductive vias 144, a plurality of upper conductive wires 146, a plurality of under-bump structures 148, a plurality of conductive bumps 150, and a passivation structure 142. A plurality of through substrate vias (TSVs) 140 extend from the second interconnect structure 106b to the upper bonding structure 112. The TSVs 140 are configured to electrically couple the second interconnect structure 106b to the upper bonding structure 112, thereby facilitating coupling the semiconductor devices of the first and second IC structures 102a, 102b to another IC device (not shown). The upper conductive vias 144 overlie the TSVs 140 and the upper conductive wires 146 overlie the upper conductive vias 144. The under-bump structures 148 are disposed on the upper conductive wires 146 and the conductive bumps 150 are disposed on the under-bump structures 148.

The first and second hybrid bond structures 108a, 108b are disposed between the first and second interconnect structures 106a, 106b and meet each other at a bond interface 103. In various embodiments, the first hybrid bond structure 108a is bonded to the second hybrid bond structure 108b by way of a hybrid bond, or some other suitable bond. In some embodiments, the first hybrid bond structure 108a comprises a first bond dielectric structure 122a, a first plurality of conductive bond vias 124a, and a first plurality of conductive bond structures 126a. In various embodiments, the second hybrid bond structure 108b comprises a second bond dielectric structure 122b, a second plurality of conductive bond vias 124b, a second plurality of conductive bond structures 126b, and a bond routing structure 110. In further embodiments, the bond routing structure 110 comprises a dielectric structure 128, a plurality of lateral routing structures 130, and a plurality of vertical routing structures 132. The first plurality of conductive bond vias 124a and the first plurality of conductive bond structures 126a are electrically coupled to the first interconnect structure 106a. The second plurality of conductive bond vias 124b and the second plurality of conductive bond structures 126b are electrically coupled to the second interconnect structure 106b by way of the lateral and vertical routing structures 130, 132. In various embodiments, the bond routing structure 110 may be configured as a hybrid bond redistribution structure, where the plurality of lateral routing structures 130 are configured as hybrid bond redistribution wires and the plurality of vertical routing structure 132 are configured as hybrid bond redistribution vias.

The first IC structure 102a is coupled to the second IC structure 102b by way of the first and second hybrid bond structures 108a, 108b. In some embodiments, the bond interface 103 comprises metal bond regions and dielectric bond regions. For example, regions in which the first and second plurality of conductive bond structures 126a, 126b contact one another define the metal bond regions, and regions in which the first and second bond dielectric structures 122a, 122b contact one another define the dielectric bond regions. In various embodiments, the metal bond regions may be electrically coupled to the first and second interconnect structures 106a, 106b.

In some embodiments, the first and second hybrid bond structures 108a, 108b comprise one or more conductive structures configured to route electrical connections between semiconductor devices of the first and/or second IC structures 102a, 102b. In such embodiments, the first and second plurality of conductive bond structures 126a, 126b and the plurality of lateral routing structures 130 may be configured to provide lateral electrical routing (e.g., horizontal routing). In addition, the first and second plurality of conductive bond vias 124a, 124b and the plurality of vertical routing structures 132 are configured to provide vertical electrical routing (e.g., vertical routing). For example, as seen in region 152 of the first and second hybrid bond structures 108a, 108b, a first lateral routing structure 130a of the plurality of lateral routing structures 130 continuously laterally extends from under the first device region 134 to under the second device region 136. This, in part, facilitates electrically coupling semiconductor devices of the first IC structure 102a to semiconductor devices of the second IC structure 102b without the corresponding semiconductor devices of the first and second IC structures 102a, 102b being aligned with one another (e.g., being laterally aligned with one another). Thus, the first and second hybrid bond structures 108a, 108b may facilitate good electrical connections and good bonding adhesion between the first and second IC structures 102a, 102b while routing electrical connections between semiconductor devices of the first and/or second IC structures 102a, 102b. Accordingly, the first and second hybrid bond structures 108a, 108b facilitate increasing design flexibility of the first and second IC structures 102a, 102b while decreases a resistance, cost of manufacturing, and/or warpage of the multi-dimensional IC structure.

FIG. 2 illustrates a perspective view 200 of some embodiments of a region of the first and second hybrid bond structures of FIG. 1. In various embodiments, the perspective view 200 of FIG. 2 corresponds to the region (152 of FIG. 1) of the first and second hybrid bond structures (108a, 108b of FIG. 1).

As illustrated in the perspective view 200 of FIG. 2, a first conductive bond via 124a of the first hybrid bond structure (108a of FIG. 1) has a first length L1 and a first width W1. In some embodiments, the first length L1 is within a range of about 0.05 micrometers (um) to about 2 um or another suitable value. In further embodiments, the first width W1 is within a range of about 0.05 um to about 2 um or another suitable value. It will be appreciated that while the first width W1 and first length L1 is provided for the first conductive bond via 124a, each of the vias in the first and second plurality of conductive bond vias (124a, 124b of FIG. 1) and the plurality of vertical routing structure (132 of FIG. 1) may have the first width W1 and the first length L1 with the range of values provided above. Further, a first conductive bond structure 126a of the first hybrid bond structure (108a of FIG. 1) has a second length L2 and a second width W2. In various embodiments, the second width W2 is within a range of about 0.5 um to about 3 um or another suitable value. In further embodiments, the second length L2 is within a range of about 0.5 um to about 10 um or another suitable value. It will be appreciated that while the second width W2 and the second length L2 is provided for the first conductive bond structure 126a, each of the conductive features in the first and second plurality of conductive bond structures (126a, 126b of FIG. 1) and the plurality of lateral routing structures (130 of FIG. 1) may have the second width W2 and the second length L2 with the range of values provided above. In various embodiments, the length L2 of the first lateral routing structure 130a is greater than lengths L2 of the first and second conductive bond structures 126a, 126b.

FIG. 3 illustrates a cross-sectional view 300 of some alternative embodiments of the multi-dimensional IC of FIG. 1, where the bond routing structure 110 comprises multiple layers of the lateral routing structures 130 and the vertical routing structures 132.

The conductive vias 120a of the first interconnect structure 106a are stacked between adjacent conductive wires in the first plurality of conductive wires 118a. Similarly, the conductive vias 120b of the second interconnect structure 106b are stacked between adjacent conductive wires in the second plurality of conductive wires 118b. In various embodiments, the first plurality of conductive bond vias 124a of the first hybrid bond structure 108a directly contact a topmost layer of the conductive wires in the first plurality of conductive wires 118a. The first plurality of conductive bond structures 126a overlie the first plurality of conductive bond vias 124a and directly contact the second plurality of conductive bond structures 126b and/or directly contact the second bond dielectric structure 122b. Thus, the first interconnect structure 106a may directly contact and/or be directly electrically coupled to the first hybrid bond structure 108a.

The bond routing structure 110 is disposed between the second interconnect structure 106b and the second hybrid bond structure 108b. In some embodiments, a top layer of the vertical routing structures 132 directly contacts a bottom layer of the second plurality of conductive wires 118b. In further embodiments, a bottom layer of the lateral routing structures 130 directly contact the second plurality of conductive bonding vias 124b. Accordingly, the second plurality of conductive bonding structures 126b is electrically coupled to the second interconnect structure 106b by way of the bond routing structure 110.

The first IC structure 102a comprises a first plurality of semiconductor devices 310 disposed in a plurality of lower device regions 302-306, where the lower device regions 302-306 are disposed within and/or on the first substrate 104a. The plurality of lower device regions 302-306 comprises a first lower device region 302, a second lower device region 304, and a third lower device region 306. Further, a plurality of lower isolation structures 312 are disposed in the first substrate 104a. The lower isolation structures 312 may, for example, be or comprise silicon dioxide, silicon nitride, silicon carbide, another dielectric material, or any combination of the foregoing and/or may be configured as a shallow trench isolation (STI) structure, a deep trench isolation (DTI) structure, or the like. The plurality of lower isolation structures 312 are each configured to demarcate a device region for a corresponding lower device region in the plurality of lower device regions 302-306 and are configured to electrically isolate semiconductor devices in the first substrate 104a from one another. In some embodiments, the lower isolation structure 312 of the first lower device region 302 demarcates an outer boundary of the first lower device region 302 and laterally encloses and/or laterally wraps around the first plurality of semiconductor devices 310 in the first lower device region 302; the lower isolation structure 312 of the second lower device region 304 demarcates an outer boundary of the second lower device region 304 and laterally encloses and/or laterally wraps around the first plurality of semiconductor devices 310 in the second lower device region 304; and the lower isolation structure 312 of the third device region 306 demarcates an outer boundary of the third lower device region 306 and laterally encloses and/or laterally wraps around the first plurality of semiconductor devices in the third lower device region 306.

In addition, the second IC structure 102b comprises a second plurality of semiconductor devices 320-324 disposed in a plurality of upper device regions 314-318, where the upper device regions 314-318 are disposed within and/or on the second substrate 104b. The second plurality of semiconductor devices 320-324 includes first semiconductor devices 320 disposed in a first upper device region 314, second semiconductor devices 322 disposed in a second upper device region 316, and third semiconductor devices 324 disposed in a third upper device region 318. A plurality of upper isolation structures 326 are disposed in the second substrate 104b. The upper isolation structures 326 may, for example, be or comprise silicon dioxide, silicon nitride, silicon carbide, another dielectric material or any combination of the foregoing and/or may be configured as a STI structure, a DTI structure, or the like. The upper isolation structures 326 are each configured to demarcate a device region for a corresponding upper device region in the plurality of upper device regions 314-318 and are configured to electrically isolate semiconductor devices in the second substrate 104b from one another. In some embodiments, the upper isolation structure 326 of the first upper device region 314 demarcates an outer boundary of the first upper device region 314 and laterally encloses and/or laterally wraps around the first semiconductor devices 320; the upper isolation structure 326 of the second upper device region 316 demarcates an outer boundary of the second upper device region 316 and laterally encloses and/or laterally wraps around the second semiconductor devices 322; and the upper isolation structure 326 of the third upper device region 318 demarcates an outer boundary of the third upper device region 318 and laterally encloses and/or laterally wraps around the third semiconductor devices 324.

In various embodiments, the first plurality of semiconductor devices 310 are a single type of IC device such as a logic device, or some other suitable device. In various embodiments, the single type of IC device may, for example, be or comprise logic transistors, logic gate(s), multiplexer(s), flip-flop(s), counter(s), another suitable logic device(s), memory device(s), static random-access memory (SRAM) device(s), or the like. In some embodiments, the first plurality of semiconductor devices 310 predominately comprise the single type of IC device such as the logic device (e.g., comprise more than about 80% of a logic device, comprise more than about 90% of a logic device, comprise more than about 95% of a logic device, comprise about 99% of a logic device, comprise about 100% of a logic device, comprise only logic devices). In various embodiments, the first plurality of semiconductor devices 310 are configured to control the operation of the devices in the second plurality of semiconductor devices 320-324. For example, in some embodiments, the first plurality of semiconductor devices 310 disposed in the first lower device region 302 are configured to control the second semiconductor devices 322 in the second upper device region 316; the first plurality of semiconductor devices 310 disposed in the second lower device region 304 are configured to control the third semiconductor devices 324 in the third upper device region 318; and the first plurality of semiconductor devices 310 disposed in the third lower device region 306 are configured to control the first semiconductor devices 320 in the first upper device region 314.

In further embodiments, the first, second, and third semiconductor devices 320-324 of the upper device regions 314-318 each predominately comprise a single type of IC device (e.g., respectively comprise more than about 80%, 90%, 95%, or 99% of a single type of IC device, comprise about 100% of a single type of IC device, comprise only a single type of IC device). In various embodiments, the first semiconductor devices 320 of the first upper device region 314 predominantly comprise semiconductor devices being of a first type of IC device (e.g., an RF device); the second semiconductor devices 322 of the second upper device region 316 predominantly comprise semiconductor devices being of a second type of IC device (e.g., an I/O device); and the third semiconductor devices 324 of the third upper device region 318 predominantly comprise semiconductor devices being of a third type of IC device (e.g., a HV device). In some embodiments, the first type of IC device, the second type of IC device, and the third type of IC device are each different from one another. In various embodiments, the first upper device region 314 may predominately comprise the first type of IC device and is devoid of the second type of IC device, devoid of the third type of IC device, and devoid of the logic device; the second upper device region 316 may predominately comprise the second type of IC device and is devoid of the first type of IC device, devoid of the third type of IC device, and devoid of the logic device; and the third upper device region 318 may predominately comprise the third type of IC device and is devoid of the first type of IC device, devoid of the second type of IC device, and devoid of the logic device. In yet further embodiments, the first upper device region 314 only comprises the first type of IC device, the second upper device region 316 only comprises the second type of IC device, and the third upper device region 318 only comprises the third type of IC device. Further, disposing the first, second, and third type of IC devices on a single substrate (e.g., the second substrate 104b) decreases a number of conductive structures (e.g., conductive wires, conductive vias, solder bumps, bonding structures, etc.) used to electrically couple semiconductor devices of the multi-dimensional IC together. This decreases fabrication costs associated with forming the multi-dimensional IC and decreases resistance in the first and second IC structures 102a, 102b.

In some embodiments, the first type of IC device of the first upper device region 314 may, for example, be or comprise RF transistor(s), RF switch(es), RF filter(s), RF amplifier(s), or another suitable RF device(s). The second type of IC device of the second upper device region 316 may, for example, be or comprise 110 transistor(s), buffer circuit(s), inverter(s), or another suitable I/O device(s). The third type of IC device of the third upper device region 318 may, for example, or comprise HV transistor(s), bipolar power transistor(s), power metal-oxide-semiconductor field-effect transistor(s) (MOSFET(s)), insulated-gate bipolar transistor(s), or another suitable HV device(s). In some embodiments, the third semiconductor devices 324 of the third upper device region 318 are configured to operate at a high voltage, whereas the first plurality of semiconductor devices 310 of the first substrate 104a are configured to operate at a low voltage less than the high voltage.

In some embodiments, the first and second hybrid bond structures 108a, 108b comprise conductive structures configured to route electrical connects between devices of the plurality of lower device regions 302-306 and devices of the plurality of upper device regions 314-318. Incorporating electrical routing in the first and second hybrid bond structures 108a, 108b removes an importance of aligning the first plurality of semiconductor devices 310 with corresponding semiconductor devices 320-324 in the plurality of upper device regions 314-318. For example, the first plurality of semiconductor devices 310 of the second lower device region 304 are configured to control the third semiconductor devices 324 of the third upper device region 318, where the second lower device region 304 is laterally offset from the third upper device region 318 by a lateral distance Ld. In some embodiments, the bond routing structure 110 comprises a first lateral routing structure 130a configured to electrically couple a semiconductor device in the second lower device region 304 to a semiconductor device in the third upper device region 318, where the first lateral routing structure 130a continuously laterally extends across the lateral distance Ld. This, in part, removes an importance of aligning (e.g., laterally aligning) the second lower device region 304 with the third upper device region 318 and decreases a number of conductive layers in the first and second interconnect structures 106a, 106b. Accordingly, design flexibility of the first and second IC structures 102a, 102b is increased and a resistance, cost of manufacturing, and/or warpage of the multi-dimensional IC structure is decreased.

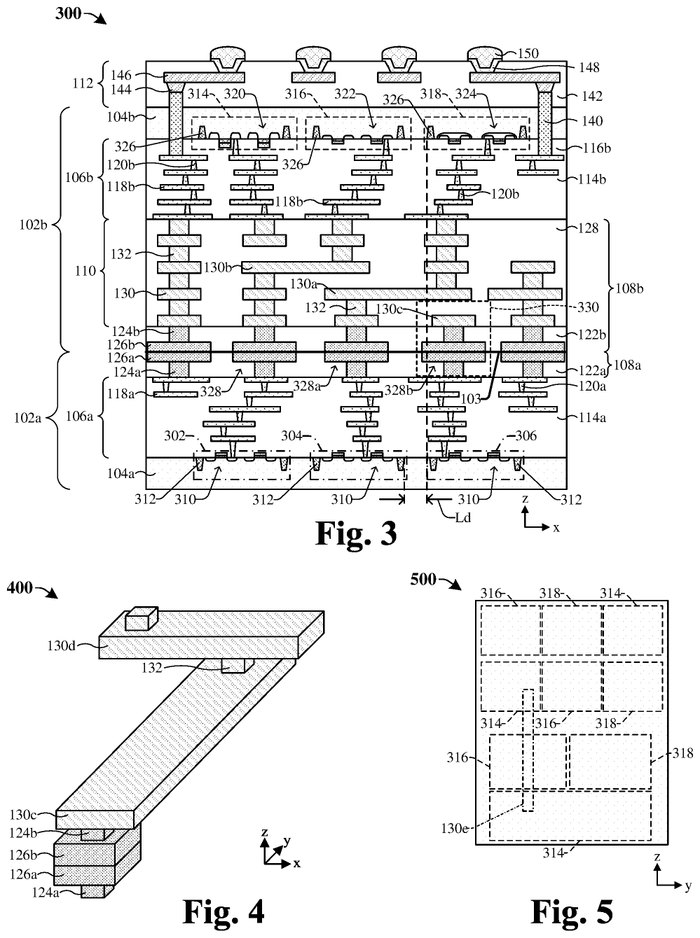

In some embodiments, the bond routing structure 110 further comprises a second lateral routing structure 130b configured to electrically couple one or more semiconductor device(s) in the first lower device region 302 to one or more semiconductor device(s) in the second upper device region 316. In such embodiments, the second lateral routing structure 130b continuously laterally traverses a region between the first lower device region 302 and the second upper device region 316. The first and second lateral routing structures 130a, 130b continuously laterally extend in a first direction (e.g., along the x-axis) and the bond routing structure 110 further comprises a third lateral routing structure 130c, in a region 330 of the first and second hybrid bond structures 108a, 108b, that continuously laterally extends in a second direction (e.g., along the y-axis) orthogonal to the first direction (e.g., see FIG. 4).

The first and second hybrid bond structures 108a, 108b meet at a bond interface 103 and define a plurality of bonded metal structures 328. Each bonded metal structure 328 comprises a first conductive bond via 124a and a first conductive bond structure 126a of the first hybrid bond structure 108a and a second conductive bond via 124b and a second conductive bond structure 126b of the second hybrid bond structure 108b. In some embodiments, the first conductive bond via 124a and the first conductive bond structure 126a of each bonded metal structure 328 may be a single continuous structure comprising a single material (e.g., copper); further the second conductive bond via 124b and the second conductive bond structure 126b of each bonded metal structure 328 may be a single continuous structure comprising a single material (e.g., copper). The plurality of bonded metal structures 328 comprises a first bonded metal structure 328a laterally offset from a second bonded metal structure 328b. In some embodiments, the first lateral routing structure 130a continuously laterally extends from over the first bonded metal structure 328a to over the second bonded metal structure 328b.

FIG. 4 illustrates a perspective view 400 of some embodiments of a region of the first and second hybrid bond structures of FIG. 3. In various embodiments, the perspective view 400 of FIG. 4 corresponds to the region (330 of FIG. 3) of the first and second hybrid bond structures (108a, 108b of FIG. 3).

As illustrated in the perspective view 400 of FIG. 4, the third lateral routing structure 130c continuously laterally extends in the second direction (e.g., along the y-axis) and a fourth lateral routing structure 130d continuously laterally extends in the first direction (e.g., along the x-axis). In some embodiments, the third and fourth lateral routing structures 130c, 130d and additional routing structures in the bond routing structure (110 of FIG. 3) are configured to electrically couple the first plurality of semiconductor devices (310 of FIG. 3) in the third lower device region (306 of FIG. 3) to the first semiconductor devices (320 of FIG. 3) in the first upper device region (314 of FIG. 3).

FIG. 5 illustrates a top view 500 of some embodiments of the multi-dimensional IC of FIG. 3, where the multi-dimensional IC comprises a plurality of first upper device regions 314, a plurality of second upper device regions 316, and a plurality of third upper device regions 318. In some embodiments, the plurality of first upper device regions 314 each comprise the first semiconductor devices (320 of FIG. 3) being of the first type of IC device (e.g., an RF device); the plurality of second upper device regions 316 each comprise the second semiconductor devices (322 of FIG. 3) being of the second type of IC device (e.g., an I/O device); and the plurality of third upper device regions 318 each comprise the third semiconductor devices (324 of FIG. 3) being of the third type of IC device (e.g., a HV device). In various embodiments, the first and second hybrid bond structures (108a, 108b of FIG. 3) are configured to route electrical connections between the pluralities of first, second, and third upper device regions 314-318 and the first plurality of semiconductor devices (310 of FIG. 3). For example, the bond routing structure (110 of FIG. 3) comprises a fifth lateral routing structure 130e configured to electrically couple semiconductor devices in adjacent first upper device regions 314 to one another. In such embodiments, the fifth lateral routing structure 130e traverses a second upper device region 316 disposed between the adjacent first upper device regions 314.

FIG. 6 illustrates a cross-sectional view 600 of some alternative embodiments of the multi-dimensional IC of FIG. 3, where a first lateral routing structure 130a of the bond routing structure 110 directly contacts a first bonded metal structure 328a and directly contacts a second bonded metal structure 328b.

FIG. 7 illustrates a perspective view 700 of some embodiments of a region of the first and second hybrid bond structures of FIG. 6. In various embodiments, the perspective view 700 of FIG. 7 corresponds to a region (602 of FIG. 6) of the first and second hybrid bond structures (108a, 108b of FIG. 6). The first lateral routing structure 130a continuously laterally extends along the first direction (e.g., along the x-axis) from the first bonded metal structure 328a to the second bonded metal structure 328b.

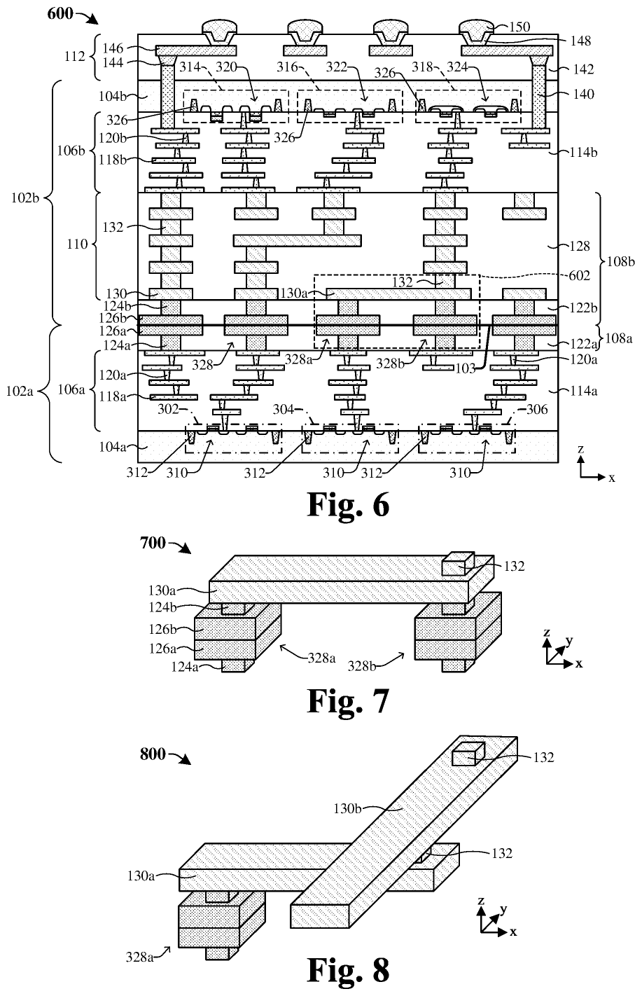

FIG. 8 illustrates a perspective view 800 of some alternative embodiments of a region of the first and second hybrid bond structures of FIG. 6. In some embodiments, the perspective view 800 of FIG. 8 corresponds to alternative embodiments of the region (602 of FIG. 6) of the first and second hybrid bond structures (108a, 108b of FIG. 6). In various embodiments, the first lateral routing structure 130a laterally extends in the first direction (e.g., along the x-axis) and comprises a first portion directly overlying the first bonded metal structure 328a and a second portion laterally offset from the first bonded metal structure 328a. Further, the second lateral routing structure 130b laterally extends in the second direction (e.g., along the y-axis) and directly overlies the second portion of the first lateral routing structure 130a.

FIG. 9 illustrates a cross-sectional view 900 of some alternative embodiments of the multi-dimensional IC of FIG. 3, where at least a portion of the second conductive bond structure 126b of the first bonded metal structure 328a directly contacts the first bond dielectric structure 122a.

In various embodiments, the second conductive bond structure 126b of the first bonded metal structure 328a comprises a single bottom surface having a first area in direct contact with the first conductive bond structure 126a of the first bonded metal structure 328a and having a second area in direct contact with the first bond dielectric structure 122a. In various embodiments, the first area is less than the second area. In yet further embodiments, the second area is at least three times greater than the first area. Further, the first area of the second conductive bond structure 126b of the first bonded metal structure 328a defines a homogenous bond region of the first bonded metal structure 328a, and the second area of the second conductive bond structure 126b of the first bonded metal structure 328a defines a heterogenous bond region of the first bonded metal structure 328a.

In yet further embodiments, a total area of the bond interface 103 is defined by an area in which the first hybrid bond structure 108a directly contacts the second hybrid bond structure 108b. In various embodiments, the total area of the bond interface 103 continuously laterally extends between opposing sidewalls of the first and second bond dielectric structures 122a, 122b. In further embodiments, the opposing sidewalls of the first bond dielectric structure 122a are aligned with the opposing sidewalls of the second bond dielectric structure 122b. The total area of the bond interface 103 includes a plurality of homogenous bond interface regions and a plurality of heterogeneous bond interface regions. In some embodiments, the homogenous bond interface regions comprise conductor-to-conductor bond regions and dielectric-to-dielectric bond regions, and the heterogenous bond interface regions comprise dielectric-to-conductor bond regions. For example, the dielectric-to-dielectric bond regions include areas of the bond interface 103 in which the first bond dielectric structure 122a directly contacts the second bond dielectric structure 122b, and the conductor-to-conductor bond regions includes areas of the bond interface 103 in which the first plurality of conductive bond structures 126a directly contact the second plurality of conductive bond structures 126b. In further embodiments, the dielectric-to-conductor bond regions include areas of the bond interface 103 in which the first bond dielectric structure 122a directly contacts portions of the second plurality of conductive bond structures 126b and areas of the bond interface 103 in which the second bond dielectric structure 122b directly contacts portions of the first plurality of conductive bond structure 126a. In some embodiments, an area of the plurality of heterogenous bond interface regions of the bond interface 103 is about 5%, about 10%, or less than about 20% of the total area of the bond interface 103. This, in part, facilities the first and second plurality of conductive bond structures 126a, 126b being used for electrical routing without degrading a strength of the bond interface 103.

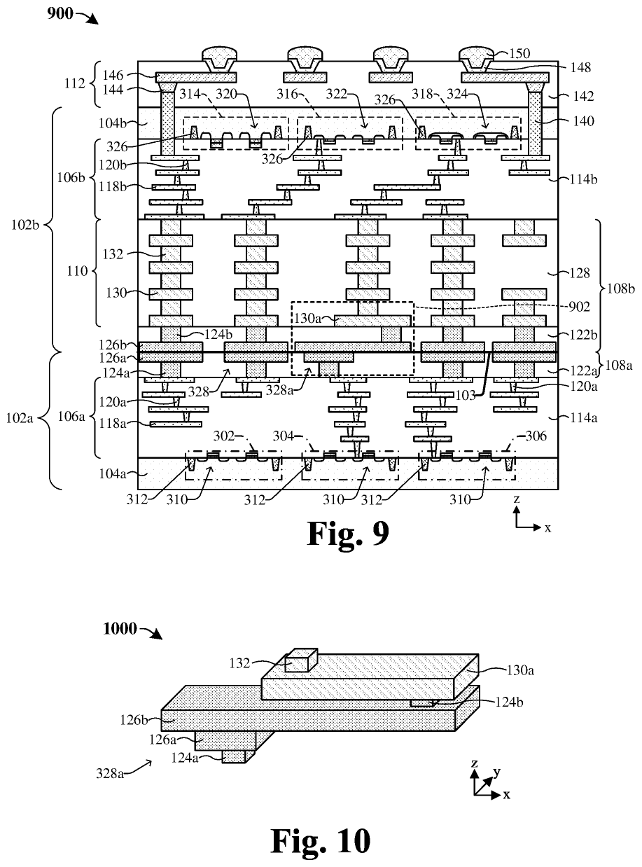

FIG. 10 illustrates a perspective view 1000 of some embodiments of a region of the first and second hybrid bond structures of FIG. 9. In various embodiments, the perspective view 1000 of FIG. 10 corresponds to a region (902 of FIG. 9) of the first and second hybrid bond structures (108a, 108b of FIG. 9). In some embodiments, the second conductive bond structure 126b of the first bonded metal structure 328a continuously laterally extends along the first direction (e.g., along the x-axis) and has a length greater than a length of the first conductive bond structure 126a of the first bonded metal structure 328a. Further, the first lateral routing structure 130a continuously laterally extends along the first direction (e.g., along the x-axis) and has a length less than the length of the second conductive bond structure 126b of the first bonded metal structure 328a.

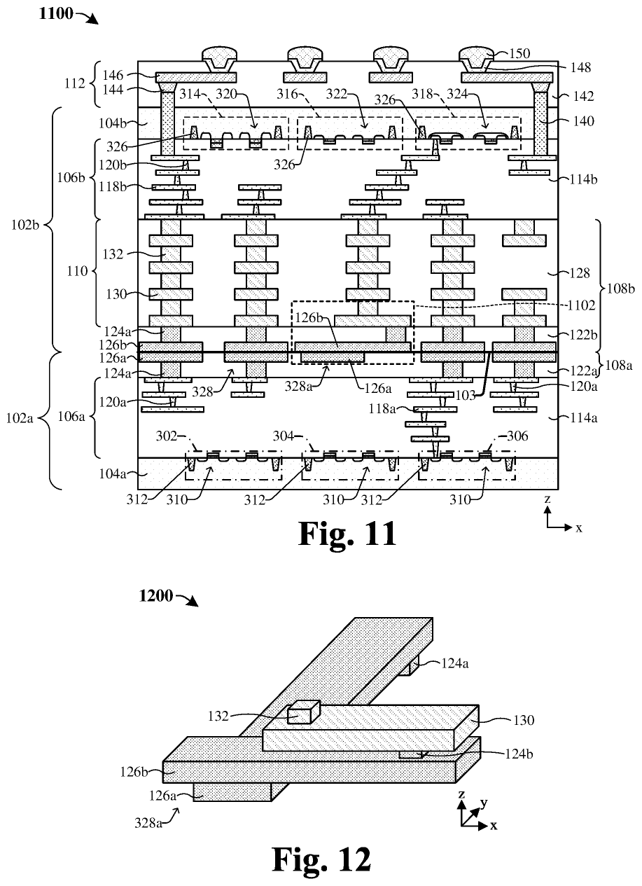

FIG. 11 illustrates a cross-sectional view 1100 of some alternative embodiments of the multi-dimensional IC of FIG. 9, where at least a portion of the second conductive bond structure 126b of the first bonded metal structure 328a directly contacts the first bond dielectric structure 122a and at least a portion of the first conductive bond structure 126a of the first bonded metal structure 328a directly contacts the second bond dielectric structure 122b (e.g., see FIG. 12).

In various embodiments, the first conductive bond structure 126a of the first bonded metal structure 328a comprises a single top surface having a first area in direct contact with the second conductive bond structure 126b of the first bonded metal structure 328a and having a second area in direct contact with the second bond dielectric structure 122b. In various embodiments, the first area is less than the second area. In yet further embodiments, the second area is at least three times greater than the first area. Further, the first area of the first conductive bond structure 126a of the first bonded metal structure 328a defines a homogenous bond region of the first bonded metal structure 328a, and the second area of the first conductive bond structure 126a of the first bonded metal structure 328a defines a heterogenous bond region of the first bonded metal structure 328a.

FIG. 12 illustrates a perspective view 1200 of some embodiments of a region of the first and second hybrid bond structures of FIG. 11. In various embodiments, the perspective view 1200 of FIG. 12 corresponds to a region (1102 of FIG. 11) of the first and second hybrid bond structures (108a, 108b of FIG. 11). In some embodiments, the second conductive bond structure 126b of the first bonded metal structure 328a continuously laterally extends along the first direction (e.g., along the x-axis) and has a length greater than a length of the first conductive bond structure 126a of the first bonded metal structure 328a. In further embodiments, the first conductive bond structure 126a of the first bonded metal structure 328a continuously laterally extends along the second direction (e.g., along the y-axis) and has a width greater than a width of the second conductive bond structure 126b of the first bonded metal structure 328a.

Although the multi-dimensional IC of FIG. 1 is illustrated with the first lateral routing structure 130a of FIG. 2, it may be appreciated, for example, that the lateral routing structures 130 from FIGS. 3-4 and 6-12 may be used in FIG. 1. In addition, any combination of the lateral routing structures 130 from FIGS. 1-4 and 6-12 may be used in any of the multi-dimensional ICs of FIGS. 1, 3, 6, 9, and/or 11. Further, although the multi-dimensional IC of FIG. 1 is illustrated with the first and second conductive bond structures 126a, 126b of FIG. 2, it may be appreciated, for example, that the first and second conductive bond structures 126a, 126b from FIGS. 3-4 and 6-12 may be used in FIG. 1. In addition, any combination of the first and second conductive bond structures 126a, 126b from FIGS. 1-4 and 6-12 may be used in any of the multi-dimensional ICs of FIGS. 1, 3, 6, 9, and/or 11. For example, the multi-dimensional IC of FIG. 3 may comprise the first and second conductive bond structures 126a, 126b of FIGS. 9-10 and/or FIGS. 11-12.

FIG. 13 illustrates a cross-sectional view 1300 of some alternative embodiments of the multi-dimensional IC of FIG. 1, where the second IC structure 102b further comprises an intermediate redistribution structure 1302 disposed between the second hybrid bond structure 108b and the second interconnect structure 106b.

In various embodiments, the intermediate redistribution structure 1302 comprises a plurality of redistribution wires 1306 and a plurality of redistribution vias 1308 disposed in a redistribution dielectric structure 1304. The plurality of redistribution wires 1306 have a thickness greater than a thickness of the second plurality of conductive wires 118b and greater than a thickness of the first and second plurality of conductive bond structures 126a, 126b. The intermediate redistribution structure 1302 is configured to route electrical connections between the first plurality of semiconductor devices 310 of the first IC structure 102a and the second plurality of semiconductor devices 320-324 disposed in the second IC structure 102b. Further, the upper bonding structure 112 comprises a first passivation layer 1310 and a second passivation layer 1312. The first passivation layer 1310 is disposed on the second substrate 104b and the second passivation layer 1312 is disposed on the first passivation layer 1310.

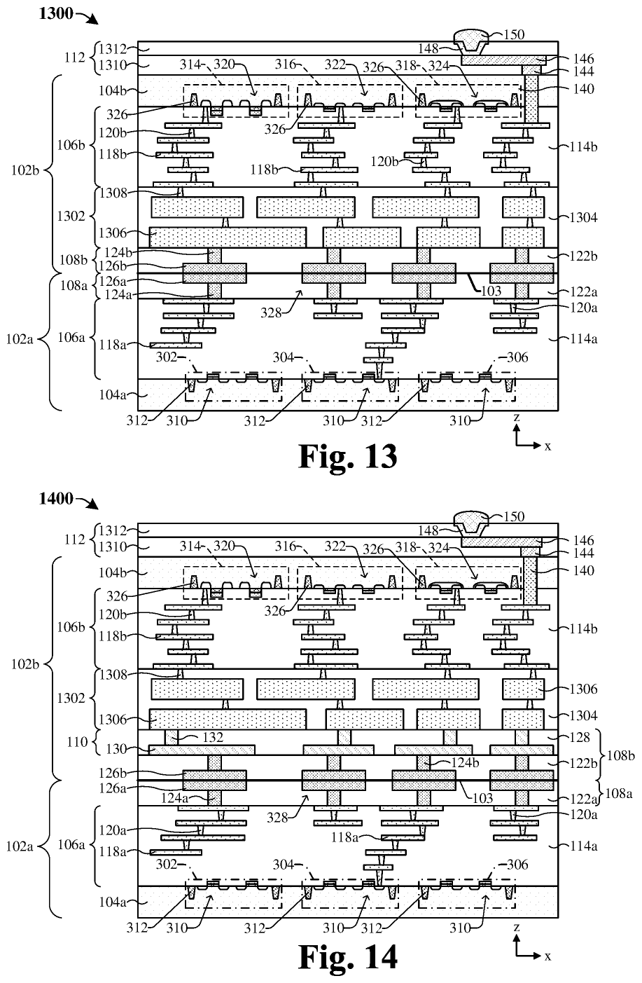

FIG. 14 illustrates a cross-sectional view 1400 of some alternative embodiments of the multi-dimensional IC of FIG. 13, where the bond routing structure 110 is disposed between the intermediate redistribution structure 1302 and the second hybrid bond structure 108b.

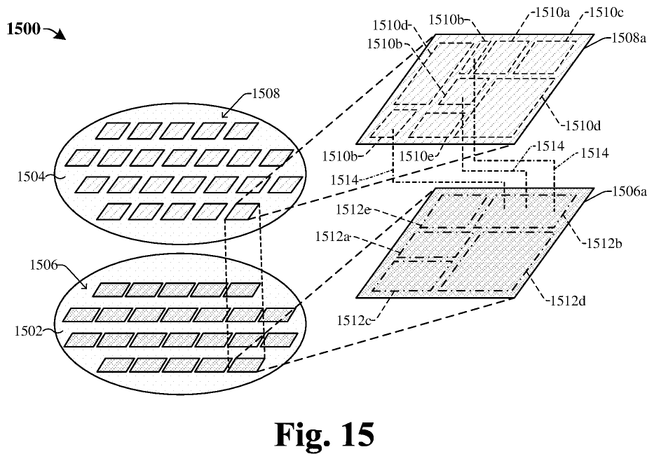

FIG. 15 illustrates a perspective view 1500 of some embodiments of a first IC structure overlying a second IC structure.

As illustrated in the perspective view 1500 of FIG. 15, an upper wafer 1504 overlies a lower wafer 1502. The lower wafer 1502 comprises a plurality of lower IC structures 1506 and the upper wafer 1504 comprises a plurality of upper IC structures 1508. In various embodiments, a first upper IC structure 1508a directly overlies a first lower IC structure 1506a. The first upper IC structure 1508a comprises a plurality of upper devices regions 1510a-e that each include semiconductor devices predominately comprising a single type of IC device. For example, the first upper device region 1510a predominately comprises a first type of IC device (e.g., RF device(s)), second upper device regions 1510b predominately comprise a second type of IC device (e.g., I/O device(s)), a third upper device region 1510c predominately comprises a third type of IC device (e.g., HV device(s)), fourth upper device regions 1510d predominately comprise a fourth type of IC device (e.g., non-volatile memory (NVM) device(s)), and a fifth upper device region 1510e predominately comprises a fifth type of IC device (e.g., an analog device). In various embodiments, the first type of IC device, the second type of IC device, the third type of IC device, the fourth type of IC device, and the fifth type of IC device are all different from one another. Further, the first lower IC structure 1506a comprises a plurality of lower device regions 1512a-e comprising semiconductor devices predominately comprising a single type of IC device (e.g., logic device(s)) configured to control corresponding device region(s) in the plurality of upper device regions 1510a-e. For example, a first lower device region 1512a predominately comprises logic devices configured to control the semiconductor devices of the first upper device region 1510a, a second lower device region 1512b predominately comprises logic devices configured to control the semiconductor devices of the second upper device regions 1510b, and so on.

In various embodiments, the first upper IC structure 1508a is bonded to the first lower IC structure 1506a and comprises a hybrid bond structure (e.g., the second hybrid bond structure 108b of FIGS. 1, 3, 6, 9, and/or 11) configured to route electrical connections between the plurality of lower device regions 1512a-e and corresponding device region(s) in the plurality of upper device regions 1510a-e. In such embodiments, the hybrid bond structure comprises one or more lateral routing structures (not shown) configured to electrically couple semiconductor devices in the second lower device region 1512b to each of the second upper device regions 1510b (as illustrated by the dashed lines 1514). This, in part, increases a flexibility of locations and/or sizes of each of the upper devices regions 1510a-e while facilitating the first upper IC structure 1508a having multiple types of IC devices on a single substrate, thereby increasing a design flexibility of the IC structures 1506a, 1508a.

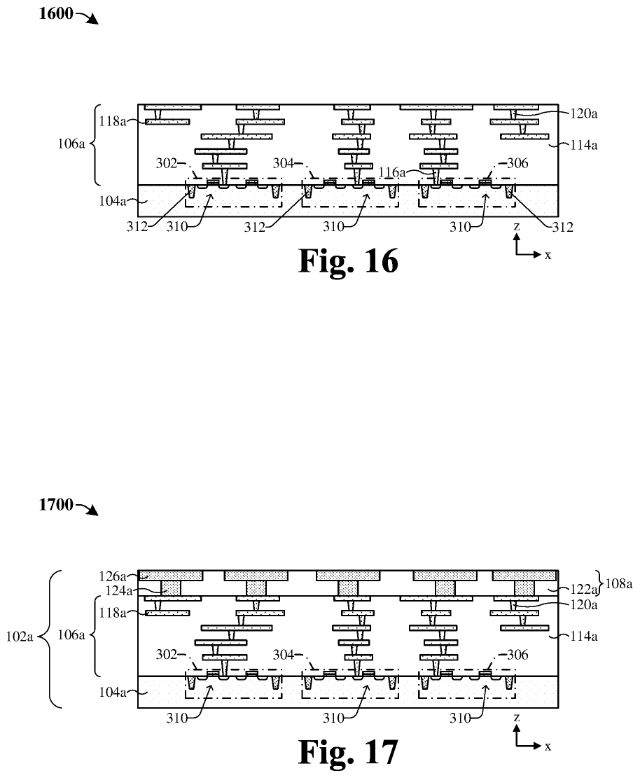

FIGS. 16-23 illustrate cross-sectional views 1600-2300 of some embodiments of a method for forming a multi-dimensional integrated circuit (IC) structure comprising a first IC structure bonded to a second IC structure, where the second IC structure comprises conductive bond layers configured to route electrical connections between the first and second IC structures. Although the cross-sectional views 1600-2300 shown in FIGS. 16-23 are described with reference to a method, it will be appreciated that the structures shown in FIGS. 16-23 are not limited to the method but rather may stand alone separate of the method. Although FIGS. 16-23 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 1600 of FIG. 16, a plurality of lower isolation structures 312 and a first plurality of semiconductor devices 310 are formed within and/or on a first substrate 104a. The first plurality of semiconductor devices 310 are disposed in a plurality of lower device regions 302-306, where the lower isolation structures 312 demarcate a device region for a corresponding lower device region in the plurality of lower device regions 302-306. In some embodiments, a process for forming the lower isolation structures 312 may include: patterning the first substrate 104a to define a plurality of trenches extending into the first substrate 104a; depositing (e.g., by chemical vapor deposition (CVD), physical vapor deposition (PVD), atomic layer deposition (ALD), etc.) a dielectric material (e.g., silicon dioxide, silicon nitride, silicon carbide, or the like) in the plurality of trenches; and performing a planarization process (e.g., a chemical mechanical planarization (CMP) process) on the dielectric material. In various embodiments, the first plurality of semiconductor devices 310 predominately comprise a single type of IC device such as a logic device, or some other suitable device. In yet further embodiments, the first plurality of semiconductor devices 310 may be formed by a first fabrication process that optimizes performance of the logic devices.

Further, as shown in the cross-sectional view 1600 of FIG. 16, a first interconnect structure 106a is formed on the first substrate 104a. The first interconnect structure 106a comprises a first plurality of conductive contacts 116a, a first plurality of conductive wires 118a, a first plurality of conductive vias 120a, and a first interconnect dielectric structure 114a. In various embodiments, the first interconnect structure 106a may be formed by one or more damascene processes (e.g., a single damascene process or a dual damascene process), and/or some other suitable fabrication process. In various embodiments, the one or more damascene processes may include: depositing (e.g., by PVD, CVD, ALD, etc.) a dielectric layer on the first substrate 104a; etching the dielectric layer to form one or more via holes and/or one or more trenches; and filling (e.g., by PVD, CVD, ALD, electroplating, electro-less plating, etc.) the one or more via holes and/or trenches with a conductive material. The dielectric layer may, for example, be or comprise silicon dioxide, a low-k dielectric material, an extreme low-k dielectric material, some other dielectric material, or any combination of the foregoing. The conductive material may, for example, be or comprise tungsten, copper, aluminum, ruthenium, titanium nitride, tantalum nitride, another conductive material, or any combination of the foregoing.

As shown in cross-sectional view 1700 of FIG. 17, a first hybrid bond structure 108a is formed on the first interconnect structure 106a, thereby defining a first IC structure 102a. In some embodiments, the first hybrid bond structure 108a comprises a first bond dielectric structure 122a, a first plurality of conductive bond vias 124a, and a first plurality of conductive bond structures 126a. In various embodiments, the first hybrid bond structure 108a may be formed by: depositing (e.g., by PVD, CVD, ALD, etc.) a dielectric layer (e.g., comprising an oxide such as silicon dioxide, or another suitable dielectric material) on the first interconnect structure 106a; etching the dielectric layer to form one or more bond via holes and/or one or more trenches; and filling (e.g., by PVD, CVD, ALD, electroplating, electro-less plating, etc.) the one or more bond via holes and/or trenches with a conductive material (e.g., copper, aluminum, tungsten, etc.). In yet further embodiments, each conductive bond via in the first plurality of conductive bond vias 124a and a corresponding conductive bond structure in the first plurality of conductive bond structures 126a are a single continuous structure comprising a single material (e.g., copper or another suitable conductive material). In yet further embodiments, a planarization process (e.g., a CMP process) is performed on the first bond dielectric structure 122a and the first plurality of conductive bond structures 126a such that a top surface of the first bond dielectric structure 122a and a top surface of the first plurality of conductive bond structures 126a are substantially flat and co-planar with one another. This, in part, mitigates non-bond areas when the first hybrid bond structure 108a is bonded to another bond structure (e.g., see FIG. 21), thereby facilitating good bond adhesion.

Further, although the structure of FIG. 17 is illustrated with the first plurality of conductive bond structures 126a of FIG. 3, it will be appreciated, that the first plurality of conductive bond structures 126a may, for example, be formed with any combination of the conductive bond structures in the first plurality of conductive bond structures 126a of FIGS. 1-4, and 6-14. More specifically, in some embodiments, one or more of the conductive bond structures in the first plurality of conductive bond structures 126a may be formed to continuously extend in a lateral direction (e.g., along the x-axis or y-axis) as illustrated in FIGS. 11 and 12.

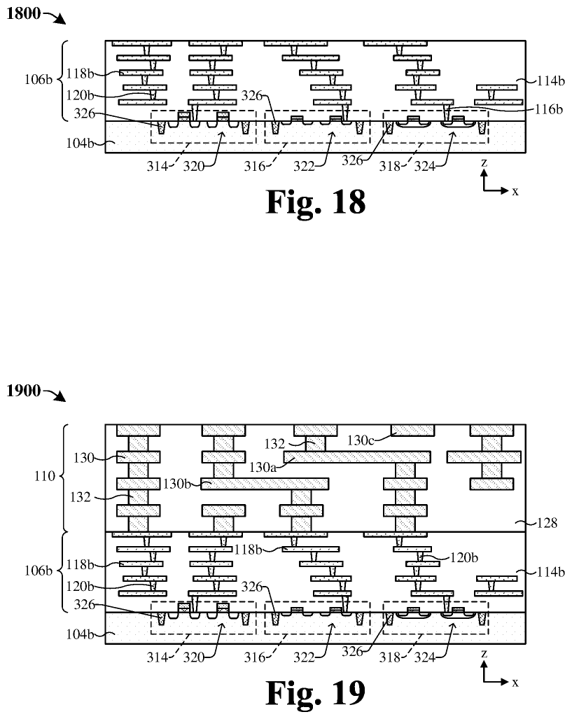

As shown in cross-sectional view 1800 of FIG. 18, a plurality of upper isolation structures 326 and a second plurality of semiconductor devices 320-324 are formed within and/or on a second substrate 104b. The second plurality of semiconductor devices 320-324 are disposed in a plurality of upper device regions 314-318, were the upper isolation structures 326 demarcate a device region for a corresponding upper device region in the plurality of upper device regions 314-318. In some embodiments, a process for forming the upper isolation structures 326 may include: patterning the second substrate 104b to define a plurality of trenches extending into the second substrate 104b; depositing (e.g., by CVD, PVD, ALD, etc.) a dielectric material (e.g., silicon dioxide, silicon nitride, silicon carbide, or the like) in the plurality of trenches; and performing a planarization process (e.g., a chemical mechanical planarization (CMP) process) on the dielectric material. The second plurality of semiconductor devices 320-324 comprises: first semiconductor devices 320 disposed in a first upper device region 314; second semiconductor devices 322 disposed in a second upper device region 316; and third semiconductor devices 324 disposed in a third upper device region 318. In various embodiments, the first semiconductor devices 320 predominately comprise a first type of IC device (e.g., an RF device), the second semiconductor devices 322 predominately comprise a second type of IC device (e.g., an I/O device), and the third semiconductor devices 324 predominately comprise a third type of IC device (e.g., a HV device). In some embodiments, the first semiconductor devices 320 are formed by a second fabrication process that optimizes performance of the first type of IC device; the second semiconductor devices 322 are formed by a third fabrication process that optimizes performance of the second type of IC device; and the third semiconductor devices 324 are formed by a fourth fabrication process that optimizes performance of the third type of IC device. In various embodiments, the first fabrication process, the second fabrication process, the third fabrication process, and the fourth fabrication process are each different from one another.

Further, as shown in the cross-sectional view 1800 of FIG. 18, a second interconnect structure 106b is formed on the second substrate 104b. The second interconnect structure 106b comprises a second plurality of conductive contacts 116b, a second plurality of conductive wires 118b, a second plurality of conductive vias 120b, and a second interconnect dielectric structure 114b. In various embodiments, the second interconnect structure 106b may be formed by one or more damascene processes (e.g., a single damascene process or a dual damascene process), and/or some other suitable fabrication process. In various embodiments, the one or more damascene processes may include: depositing (e.g., by PVD, CVD, ALD, etc.) a dielectric layer on the second substrate 104b; etching the dielectric layer to form one or more via holes and/or one or more trenches; and filling (e.g., by PVD, CVD, ALD, electroplating, electro-less plating, etc.) the one or more via holes and/or trenches with a conductive material. The dielectric layer may, for example, be or comprise silicon dioxide, a low-k dielectric material, an extreme low-k dielectric material, some other dielectric material, or any combination of the foregoing. The conductive material may, for example, be or comprise tungsten, copper, aluminum, ruthenium, titanium nitride, tantalum nitride, another conductive material, or any combination of the foregoing.

As shown in cross-sectional view 1900 of FIG. 19, a bond routing structure 110 is formed on the second interconnect structure 106b. The bond routing structure 110 comprises a dielectric structure 128, a plurality of lateral routing structures 130, and a plurality of vertical routing structures 132. In various embodiments, the bond routing structure 110 may be formed by one or more damascene processes (e.g., a single damascene process or a dual damascene process), and/or some other suitable fabrication process. In various embodiments, the one or more damascene processes may include: depositing (e.g., by PVD, CVD, ALD, etc.) a dielectric layer on the second substrate 104b; etching the dielectric layer to form one or more holes and/or one or more trenches; and filling (e.g., by PVD, CVD, ALD, electroplating, electro-less plating, etc.) the one or more holes and/or trenches with a conductive material. The dielectric layer may, for example, be or comprise silicon dioxide, a low-k dielectric material, an extreme low-k dielectric material, some other dielectric material, or any combination of the foregoing. The conductive material may, for example, be or comprise tungsten, copper, aluminum, ruthenium, another conductive material, or any combination of the foregoing.

In further embodiments, the bond routing structure may comprise a first lateral routing structure 130a, a second lateral routing structure 130b, a third lateral routing structure 130c, and/or another lateral routing structure as illustrate and/or described in FIGS. 3 and 4. Further, although the structure of FIG. 19 is illustrated with the lateral routing structures 130a-c of FIGS. 3 and 4, it will be appreciated, that the bond routing structure 110 may, for example, be formed with any combination of the lateral and vertical routing structures 130, 132 of FIGS. 1-4, and 6-14.

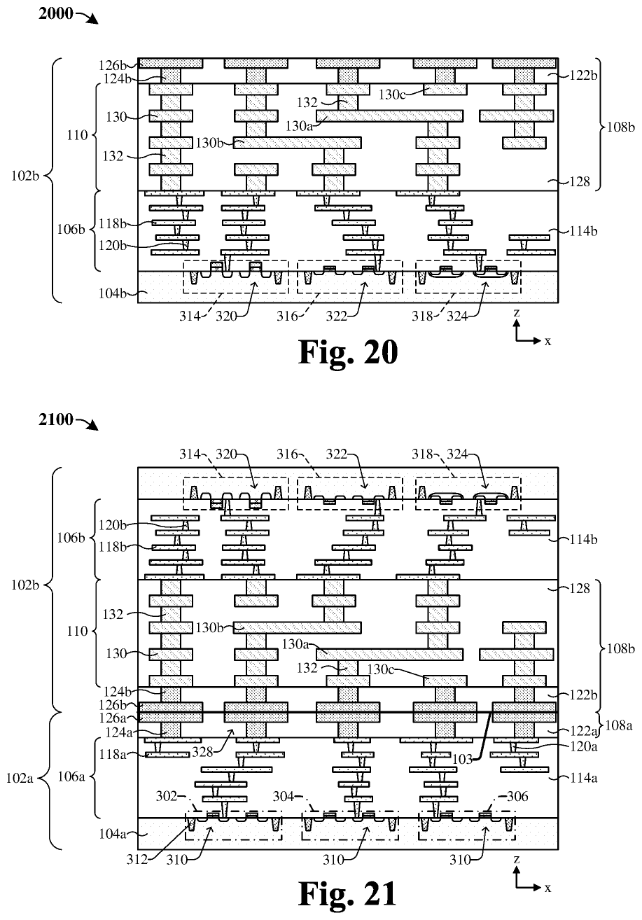

As shown in cross-sectional view 2000 of FIG. 20, a second bond dielectric structure 122b, a second plurality of conductive bond vias 124b, and a second plurality of conductive bond structures 126b are formed on the bond routing structure 110, thereby defining a second hybrid bond structure 108b over the second substrate 104b and a second IC structure 102b. In various embodiments, the second bond dielectric structure 122b, the second plurality of conductive bond vias 124b, and the second plurality of conductive bond structures 126b may be formed by: depositing (e.g., by PVD, CVD, ALD, etc.) a dielectric layer (e.g., comprising an oxide such as silicon dioxide, or another suitable dielectric material) on the bond routing structure 110; etching the dielectric layer to form one or more bond via holes and/or one or more trenches; and filling (e.g., by PVD, CVD, ALD, electroplating, electro-less plating, etc.) the one or more bond via holes and/or trenches with a conductive material (e.g., copper, aluminum, tungsten, etc.). In yet further embodiments, each conductive bond via in the second plurality of conductive bond vias 124b and a corresponding conductive bond structure in the second plurality of conductive bond structures 126b are a single continuous structure comprising a single material (e.g., copper or another suitable conductive material). In yet further embodiments, a planarization process (e.g., a CMP process) is performed on the second bond dielectric structure 122b and the second plurality of conductive bond structures 126b such that a top surface of the second bond dielectric structure 122b and a top surface of the second plurality of conductive bond structures 126b are substantially flat and co-planar with one another. This, in part, mitigates non-bond areas when the second hybrid bond structure 108b is bonded to another bond structure (e.g., see FIG. 21), thereby facilitating good bond adhesion.

Further, although the structure of FIG. 20 is illustrated with the second plurality of conductive bond structures 126b of FIG. 3, it will be appreciated, that the second plurality of conductive bond structures 126b may, for example, be formed with any combination of the conductive bond structures in the second plurality of conductive bond structures 126b of FIGS. 1-4, and 6-14. More specifically, in some embodiments, one or more of the conductive bond structures in the second plurality of conductive bond structures 126b may be formed to continuously extend in a lateral direction (e.g., along the x-axis or y-axis) as illustrated in FIGS. 9-12.

As shown in cross-sectional view 2100 of FIG. 21, the second IC structure 102b is rotated and bonded to the first IC structure 102a such that the first and second hybrid bond structures 108a, 108b meet at a bond interface 103 and an define a plurality of bonded metal structures 328. In some embodiments, the second IC structure 102b may be bonded to the first IC structure 102a by way of a hybrid bonding process. In such embodiments, the first plurality of conductive bond structures 126a are brought in contact with the second plurality of conductive bond structures 126b and the first bond dielectric structure 122a is brought in contact with the second bond dielectric structure 122b. In various embodiments, temperatures of the first and second hybrid bond structures 108a, 108b are increased to form the plurality of bonded metal structures 328 and the bond interface. In further embodiments, a direct bonding process, a eutectic bonding process, or another suitable bonding process may be used to bond the first IC structure 102a to the second IC structure 102b. Further, a total area of the bond interface 103 includes a plurality of homogenous bond interface regions and a plurality of heterogeneous bond interface regions. In some embodiments, an area of the plurality of heterogenous bond interface regions of the bond interface 103 is about 5%, about 10%, or less than about 20% of the total area of the bond interface 103.

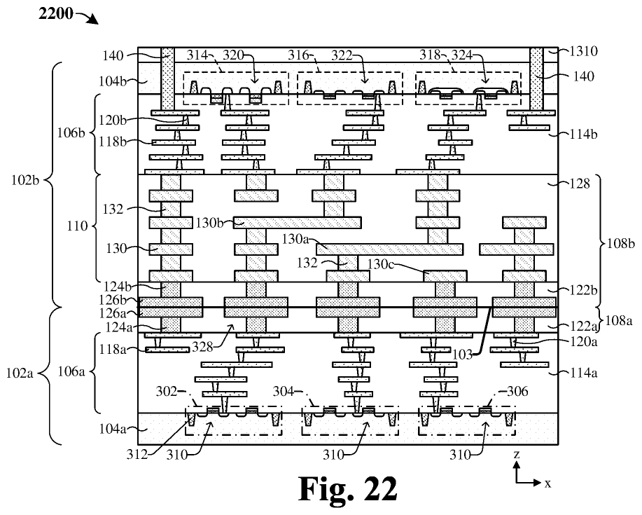

As shown in cross-sectional view 2200 of FIG. 22, a plurality of TSVs 140 are formed extending through the second substrate 104b. In some embodiments, a process for forming the plurality of TSVs 140 comprises: depositing (e.g., by CVD, PVD, ALD, etc.) a first passivation layer 1310 over the second substrate 104b; etching the first passivation layer 1310 and the second substrate 104b to form TSV openings extending through the second substrate 104b; and filling (e.g., by PVD, CVD, ALD, electroplating, electro-less plating, etc.) the TSV openings with a conductive material (e.g., copper, aluminum, tungsten, etc.).

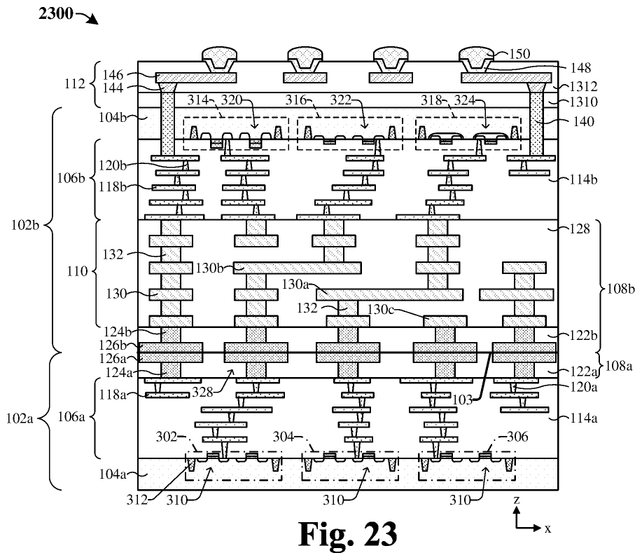

As shown in cross-sectional view 2300 of FIG. 23, a plurality of upper conductive vias 144, a plurality of upper conductive wires 146, a plurality of under-bump structures 148, a plurality of conductive bumps 150, and a second passivation layer 1312 are formed over the second substrate 104b, thereby defining an upper bonding structure 112. In various embodiments, the second passivation layer 1312 may be formed by a CVD process, a PVD process, an ALD process, or some other suitable deposition process. Further, the plurality of upper conductive vias 144 and the plurality of upper conductive wires 146 may, for example, be formed by one or more damascene processes (e.g., a single damascene process or a dual damascene process) or some other suitable fabrication process.

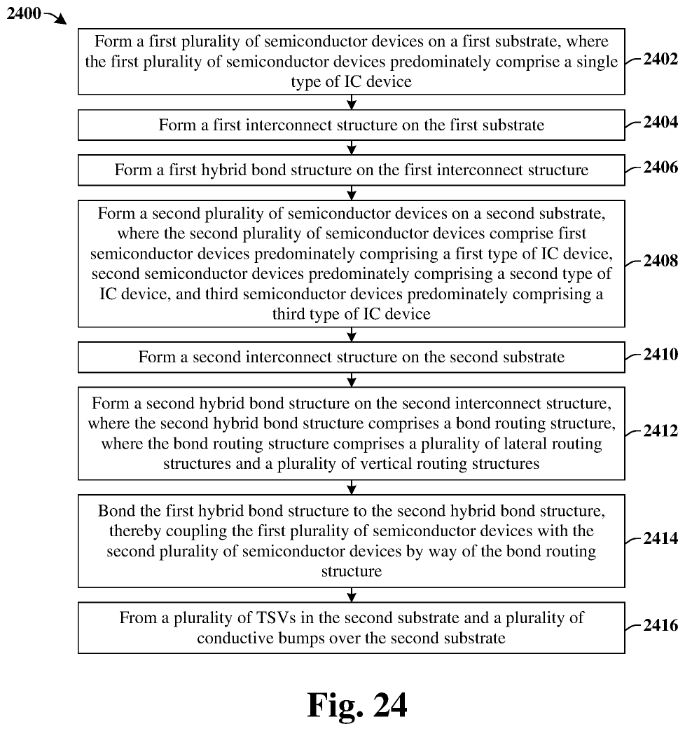

FIG. 24 illustrates a flowchart 2400 of some embodiments of a method for forming a multi-dimensional IC structure comprising a first IC structure bonded to a second IC structure, where the second IC structure comprises conductive bond layers configured to route electrical connections between the first and second IC structures. Although the flowchart 2400 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2402, a first plurality of semiconductor devices is formed on a first substrate, where the first plurality of semiconductor devices predominately comprises a single type of IC device. FIG. 16 illustrates cross-sectional view 1600 corresponding to various embodiments of act 2402.

At act 2404, a first interconnect structure is formed on the first substrate. FIG. 16 illustrates cross-sectional view 1600 corresponding to various embodiments of act 2404.

At act 2406, a first hybrid bond structure is formed on the first interconnect structure. FIG. 17 illustrates cross-sectional view 1700 corresponding to various embodiments of act 2406.

At act 2408, a second plurality of semiconductor devices are formed on a second substrate, where the second plurality of semiconductor devices comprise first semiconductor devices predominately comprising a first type of IC device, second semiconductor devices predominately comprising a second type of IC device, and third semiconductor devices predominately comprising a third type of IC device. FIG. 18 illustrates cross-sectional view 1800 corresponding to various embodiments of act 2408.

At act 2410, a second interconnect structure is formed on the second substrate. FIG. 18 illustrates cross-sectional view 1800 corresponding to various embodiments of act 2410.

At act 2412, a second hybrid bond structure is formed on the second interconnect structure, where the second hybrid bond structure comprises a bond routing structure, where the bond routing structure comprises a plurality of lateral routing structures and a plurality of vertical routing structures. FIGS. 19 and 20 illustrate cross-sectional views 1900 and 2000 corresponding to various embodiments of act 2412.

At act 2414, the first hybrid bond structure is bonded to the second hybrid bond structure, thereby coupling the first plurality of semiconductor devices with the second plurality of semiconductor devices by way of the bond routing structure. FIG. 21 illustrates cross-sectional view 2100 corresponding to various embodiments of act 2414.

At act 2416, a plurality of TSVs are formed in the second substrate and a plurality of conductive bumps are formed over the second substrate. FIGS. 22 and 23 illustrate cross-sectional views 2200 and 2300 corresponding to various embodiments of act 2416.

Accordingly, in some embodiments, the present disclosure relates to a first IC structure comprising a first plurality of semiconductor devices predominately comprising a single type of IC device vertically stacked with a second IC structure comprising a second plurality of semiconductor devices comprising different types of IC devices, where the second IC structure comprising a bond routing structure configured to route electrical connections between the first plurality of semiconductor devices and the second plurality of semiconductor devices.

In some embodiments, the present application provides an integrated circuit (IC) including: a first IC structure comprising a first substrate, a first interconnect structure on the first substrate, and a first hybrid bond structure on the first interconnect structure; a second IC structure comprising a second substrate, a second interconnect structure on the second substrate, a second hybrid bond structure on the second interconnect structure, wherein a bond interface is between the first hybrid bond structure and the second hybrid bond structure, wherein the second substrate comprises a first device region comprising first semiconductor devices and a second device region comprising second semiconductor devices, the first semiconductor devices being of a first type of IC device and the second semiconductor devices being of a second type of IC device different from the first type of IC device; and a bond routing structure disposed in the second hybrid bonding structure, wherein the bond routing structure couples the first interconnect structure to the first semiconductor devices and the second semiconductor devices, wherein the bond routing structure comprises a lateral routing structure that continuously laterally extends from under the first device region to under the second device region. In an embodiment, the first device region is laterally offset from the second device region by a lateral distance, and the lateral routing structure continuously extends across the lateral distance. In an embodiment, the IC further includes a third semiconductor device disposed on the first substrate, wherein the third semiconductor device directly underlies the first device region, and wherein the lateral routing structure directly couples the third semiconductor device to at least one of the second semiconductor devices. In an embodiment, the third semiconductor device is a third type of IC device different from the first and second type of IC devices. In an embodiment, the first type of IC device is an input/output device, the second type of IC device is a high voltage device, and the third type of IC device is a logic device. In an embodiment, the first hybrid bond structure comprises a first conductive bond structure disposed in a first dielectric bond structure, wherein the second hybrid bond structure comprises a second conductive bond structure directly contacting the first conductive bond structure and the first dielectric bond structure at the bond interface. In an embodiment, the second conductive bond structure comprises a single bottom surface having a first area in direct contact with the first conductive bond structure and a second area in direct contact with the first dielectric bond structure, wherein the second area is greater than the first area. In an embodiment, the first area of the single bottom surface comprises a homogenous bond interface with the first conductive bond structure and the second area of the single bottom surface comprises a heterogenous bond interface with the first dielectric bond structure.

In some embodiments, the present application provides an integrated circuit (IC) including: a plurality of first semiconductor devices disposed on a first substrate, wherein the first semiconductor devices predominately comprise a first type of IC device; a first hybrid bond structure disposed on the first substrate and comprising a plurality of first conductive bond structures; a plurality of second semiconductor devices disposed on a second substrate, wherein the second semiconductor devices predominately comprise a second type of IC device different from the first type of IC device; a second hybrid bond structure disposed on the second substrate and comprising a plurality of second conductive bond structures, wherein a bond interface is between the plurality of first conductive bond structures and the plurality of second conductive bond structures and defines a plurality of bonded metal structures, wherein the plurality of bonded metal structures comprises a first bonded metal structure laterally offset from a second bonded metal structure; and a bond routing structure disposed in the second hybrid bonding structure between the plurality of second conductive bond structures and the second substrate, wherein the bond routing structure couples the first semiconductor devices to the second semiconductor devices, wherein the bond routing structure comprises a lateral routing structure that has a first portion directly overlying the first bonded metal structure and a second portion directly overlying the second bonded metal structure. In an embodiment, the lateral routing structure directly contacts the first bonded metal structure and is offset from the second bonded metal structure by a non-zero distance. In an embodiment, the lateral routing structure directly contacts the first bonded metal structure and directly contacts the second bonded metal structure. In an embodiment, a width of the lateral routing structure is equal to a width of the first bonded metal structure and a length of the lateral routing structure is greater than lengths of the first and second bonded metal structures. In an embodiment, the first type of IC device comprises a logic device. In an embodiment, the IC further includes a plurality of third semiconductor devices disposed on the second substrate, wherein the third semiconductor devices predominately comprise a third type of IC device different from the second type of IC device, wherein a first isolation structure is disposed in the second substrate and laterally encloses the second semiconductor devices and a second isolation structure is disposed in the second substrate and laterally encloses the third semiconductor devices, wherein the lateral routing structure directly underlies a portion of the first isolation structure and directly underlies a portion of the second isolation structure. In an embodiment, the first bonded metal structure is spaced between sidewalls of the first isolation structure and the second bonded metal structure is spaced between sidewalls of the second isolation structure. In an embodiment, a total area of the bond interface comprises a plurality of homogenous bond interface regions and a plurality of heterogenous bond interface regions, wherein an area of the heterogenous bond interface regions of the bond interface is less than about 20% of the total area of the bond interface.

In some embodiments, the present application provides a method for forming an integrated circuit (IC), the method including: forming a plurality of first semiconductor devices on a first substrate, wherein the first semiconductor devices predominately comprise a first type of IC device and are formed by a first fabrication process; forming a first hybrid bond structure on the first substrate; forming a plurality of second semiconductor devices on a second substrate, wherein the second semiconductor devices predominately comprise a second type of IC device different from the first type of IC device, wherein the second semiconductor devices are formed by a second fabrication process different than the first fabrication process; forming a second hybrid bond structure on the second substrate, wherein the second hybrid bond structure comprises a lateral routing structure; and bonding the first hybrid bond structure to the second hybrid bond structure such that the second semiconductor devices are laterally offset from at least one of the first semiconductor devices by a non-zero distance, wherein the lateral routing structure continuously extends along the non-zero distance and electrically couples the at least one of the first semiconductor devices to the second semiconductor devices. In an embodiment, bonding the first hybrid bond structure to the second hybrid bond structure defines a plurality of bonded metal structures, wherein the plurality of bonded metal structures comprises a first bonded metal structure, wherein the first bonded metal structure comprises a first conductive bond structure that continuously laterally extends in a first direction. In an embodiment, the first bonded metal structure further comprises a second conductive bond structure that continuously laterally extends in a second direction orthogonal to the first direction, wherein the first conductive bond structure directly contacts the second conductive bond structure, and wherein the lateral routing structure continuously laterally extends in the second direction. In an embodiment, the method further includes forming a plurality of third semiconductor devices on the second substrate laterally offset from the second semiconductor devices, wherein the third semiconductor devices predominately comprise a third type of IC device and are formed by a third fabrication process different from the second fabrication process, wherein the third type of IC device is different from the second type of IC device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) comprising:
a first IC structure comprising a first substrate, a first interconnect structure on the first substrate, and a first hybrid bond structure on the first interconnect structure;
a second IC structure comprising a second substrate, a second interconnect structure on the second substrate, a second hybrid bond structure on the second interconnect structure, wherein a bond interface is between the first hybrid bond structure and the second hybrid bond structure, wherein the second substrate comprises a first device region comprising first semiconductor devices and a second device region comprising second semiconductor devices, the first semiconductor devices being of a first type of IC device and the second semiconductor devices being of a second type of IC device different from the first type of IC device; and
a bond routing structure disposed in the second hybrid bonding structure, wherein the bond routing structure couples the first interconnect structure to the first semiconductor devices and the second semiconductor devices, wherein the bond routing structure comprises a lateral routing structure that continuously laterally extends from under the first device region to under the second device region.

2. The IC of claim 1, wherein the first device region is laterally offset from the second device region by a lateral distance, and wherein the lateral routing structure continuously extends across the lateral distance.

3. The IC of claim 1, further comprising:
a third semiconductor device disposed on the first substrate, wherein the third semiconductor device directly underlies the first device region, and wherein the lateral routing structure directly couples the third semiconductor device to at least one of the second semiconductor devices.

4. The IC of claim 3, wherein the third semiconductor device is a third type of IC device different from the first and second type of IC devices.

5. The IC of claim 4, wherein the first type of IC device is an input/output device, the second type of IC device is a high voltage device, and the third type of IC device is a logic device.

6. The IC of claim 1, wherein the first hybrid bond structure comprises a first conductive bond structure disposed in a first dielectric bond structure, wherein the second hybrid bond structure comprises a second conductive bond structure directly contacting the first conductive bond structure and the first dielectric bond structure at the bond interface.

7. The IC of claim 6, wherein the second conductive bond structure comprises a single bottom surface having a first area in direct contact with the first conductive bond structure and a second area in direct contact with the first dielectric bond structure, wherein the second area is greater than the first area.

8. The IC of claim 7, wherein the first area of the single bottom surface comprises a homogenous bond interface with the first conductive bond structure and the second area of the single bottom surface comprises a heterogenous bond interface with the first dielectric bond structure.

9. An integrated circuit (IC) comprising:
a plurality of first semiconductor devices disposed on a first substrate, wherein the first semiconductor devices predominately comprise a first type of IC device;
a first hybrid bond structure disposed on the first substrate and comprising a plurality of first conductive bond structures;
a plurality of second semiconductor devices disposed on a second substrate, wherein the second semiconductor devices predominately comprise a second type of IC device different from the first type of IC device;
a second hybrid bond structure disposed on the second substrate and comprising a plurality of second conductive bond structures, wherein a bond interface is between the plurality of first conductive bond structures and the plurality of second conductive bond structures and defines a plurality of bonded metal structures, wherein the plurality of bonded metal structures comprises a first bonded metal structure laterally offset from a second bonded metal structure; and
a bond routing structure disposed in the second hybrid bonding structure between the plurality of second conductive bond structures and the second substrate, wherein the bond routing structure couples the first semiconductor devices to the second semiconductor devices, wherein the bond routing structure comprises a lateral routing structure that has a first portion directly overlying the first bonded metal structure and a second portion directly overlying the second bonded metal structure.

10. The IC of claim 9, wherein the lateral routing structure directly contacts the first bonded metal structure and is offset from the second bonded metal structure by a non-zero distance.

11. The IC of claim 9, wherein the lateral routing structure directly contacts the first bonded metal structure and directly contacts the second bonded metal structure.

12. The IC of claim 9, wherein a width of the lateral routing structure is equal to a width of the first bonded metal structure and a length of the lateral routing structure is greater than lengths of the first and second bonded metal structures.

13. The IC of claim 9, wherein the first type of IC device comprises a logic device.

14. The IC of claim 9, further comprising:
a plurality of third semiconductor devices disposed on the second substrate, wherein the third semiconductor devices predominately comprise a third type of IC device different from the second type of IC device, wherein a first isolation structure is disposed in the second substrate and laterally encloses the second semiconductor devices and a second isolation structure is disposed in the second substrate and laterally encloses the third semiconductor devices, wherein the lateral routing structure directly underlies a portion of the first isolation structure and directly underlies a portion of the second isolation structure.

15. The IC of claim 14, wherein the first bonded metal structure is spaced between sidewalls of the first isolation structure and the second bonded metal structure is spaced between sidewalls of the second isolation structure.

16. The IC of claim 15, wherein a total area of the bond interface comprises a plurality of homogenous bond interface regions and a plurality of heterogenous bond interface regions, wherein an area of the heterogenous bond interface regions of the bond interface is less than about 20% of the total area of the bond interface.

17. A method for forming an integrated circuit (IC), the method comprising:
forming a plurality of first semiconductor devices on a first substrate, wherein the first semiconductor devices predominately comprise a first type of IC device and are formed by a first fabrication process;
forming a first hybrid bond structure on the first substrate;
forming a plurality of second semiconductor devices on a second substrate, wherein the second semiconductor devices predominately comprise a second type of IC device different from the first type of IC device, wherein the second semiconductor devices are formed by a second fabrication process different than the first fabrication process;
forming a second hybrid bond structure on the second substrate, wherein the second hybrid bond structure comprises a lateral routing structure; and
bonding the first hybrid bond structure to the second hybrid bond structure such that the second semiconductor devices are laterally offset from at least one of the first semiconductor devices by a non-zero distance, wherein the lateral routing structure continuously extends along the non-zero distance and electrically couples the at least one of the first semiconductor devices to the second semiconductor devices.

18. The method of claim 17, wherein bonding the first hybrid bond structure to the second hybrid bond structure defines a plurality of bonded metal structures, wherein the plurality of bonded metal structures comprises a first bonded metal structure, wherein the first bonded metal structure comprises a first conductive bond structure that continuously laterally extends in a first direction.

19. The method of claim 18, wherein the first bonded metal structure further comprises a second conductive bond structure that continuously laterally extends in a second direction orthogonal to the first direction, wherein the first conductive bond structure directly contacts the second conductive bond structure, and wherein the lateral routing structure continuously laterally extends in the second direction.

20. The method of claim 17, further comprising:
forming a plurality of third semiconductor devices on the second substrate laterally offset from the second semiconductor devices, wherein the third semiconductor devices predominately comprise a third type of IC device and are formed by a third fabrication process different from the second fabrication process, wherein the third type of IC device is different from the second type of IC device.
